(19) United States
(12) Patent Application Publication
(10) Pub. No.: US 2025/0231870 A1
(43) Pub. Date: Jul. 17, 2025

(54) DATA STORAGE DEVICE, DATA STORAGE MEDIUM, AND DATA REFRESH METHOD

(71) Applicant: Silicon Motion, Inc., Jhubei City (TW)

(72) Inventor: Hung Yi Wu, Zhubei City (TW)

(21) Appl. No.: 19/014,299

(22) Filed: Jan. 9, 2025

(30) Foreign Application Priority Data
Jan. 12, 2024 (TW) 113101432

(51) Int. Cl. G06F 12/02

(52) U.S. Cl. CPC G06F 12/0246

(57) ABSTRACT

A data storage device, medium and a data refresh method are provided. The data storage device includes the data storage medium storing a plurality of instructions. The data refresh method is performed by executing the instructions, which includes: receiving a data reading instruction from a host; determining whether a data block is read for the first time within a cycle, where the data block is searched for based on the data reading instruction; in response to the data block being read for the first time within the cycle, adding a first value to a read count of the data block; determining whether the read count increased is greater than a refresh threshold; and in response to the read count increased being greater than the refresh threshold, performing a refresh operation on the data block. Therefore, the read count is increased to perform the refresh operation on the data block earlier.

### FIELD OF THE INVENTION

The present invention relates to a data storage device, a data storage medium, and a data refresh method, and more particularly to a data storage device, a data storage medium, and a data refresh method for preserving data integrity.

### BACKGROUND OF THE INVENTION

Due to the evolution of the flash memory fabrication process, some data blocks or data pages in some types of flash memories are prone to latent read disturbance when frequently read within a cycle, especially for least significant bit (LSB) data pages, and this latent read disturbance is likely to occur when read counts of these data blocks or data pages have not yet reached a refresh threshold. Therefore, a data storage device, a data storage medium, and a data refresh method capable of preserving data from read disturbance are needed.

### SUMMARY OF THE INVENTION

The present invention provides a data storage device, a data storage medium, and a data refresh method capable of effectively preserving data integrity.

The data storage device provided by the present invention includes a non-volatile flash memory and a controller, where the non-volatile flash memory includes a plurality of data blocks, and the controller is coupled to the non-volatile flash memory and configured to perform a data refresh method. The data refresh method includes: receiving a data reading instruction from a host; determining whether a data block is read for the first time within a cycle, where the data block is searched for based on the data reading instruction; in response to that the data block is read for the first time within the cycle, adding a first value to a read count of the data block; determining whether the read count increased is greater than a refresh threshold; and in response to that the read count increased is greater than the refresh threshold, performing a refresh operation on the data block.

The data storage medium provided by the present invention is configured to store a plurality of instructions, where the plurality of instructions are executed by a controller to perform a data refresh method which includes: receiving a data reading instruction from a host; determining whether a data block is read for the first time within a cycle, where the data block is searched for based on the data reading instruction; in response to that the data block is read for the first time within the cycle, adding a first value to a read count of the data block; determining whether the read count increased is greater than a refresh threshold; and in response to that the read count increased is greater than the refresh threshold, performing a refresh operation on the data block.

The data refresh method provided by the present invention is applicable to a data storage device including a non-volatile flash memory and a controller, where the non-volatile flash memory includes a plurality of data blocks, and the controller performs a data refresh method which includes: receiving a data reading instruction from a host; determining whether a data block is read for the first time within a cycle, where the data block is searched for based on the data reading instruction; in response to that the data block is read for the first time within the cycle, adding a first value to a read count of the data block; determining whether the read count increased is greater than a refresh threshold; and in response to that the read count increased is greater than the refresh threshold, performing a refresh operation on the data block.

In an embodiment of the present invention, the data refresh method further includes: in response to that the data block is not read for the first time within the cycle, adding a second value to the read count of the data block, where the second value is less than the first value.

In an embodiment of the present invention, the second value is 1.

In an embodiment of the present invention, the cycle is at least 120 seconds.

In an embodiment of the present invention, the first value is at least 120.

In an embodiment of the present invention, the refresh threshold is at least 50,000.

According to the present invention, the weighted value is added to the read count of the data block frequently read within a cycle. Compared with a conventional count reading mode in which 1 is added to the read count of the data block when the data block is read once, the read count of the data block in the present invention reaches the refresh threshold more quickly, such that the refresh operation on the data block can be performed earlier and the impact of latent read disturbance on data blocks, data pages, and data can be avoided.

Other objectives, features and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

FIG. 1 is a system block diagram of a data storage device provided by an embodiment of the present invention; and

FIG. 2 is a flowchart of steps of a data refresh method provided by an embodiment of the present invention.

### DETAILED DESCRIPTION OF PREFERRED EMBODIMENTS

The present invention is particularly described with the following examples, which are only for illustrative purposes. Various changes and modifications may be made by those skilled in the art without departing from the spirit and scope of the present disclosure. Therefore, the scope of protection of the present disclosure should be subject to the scope of patent application appended. Throughout the specification and the scope of patent application, the meaning of “a/an” and “the” refers to that such description includes “a/an or at least a/an” element or component, unless the content clearly specifies otherwise. In addition, as used in the present invention, the singular article also includes the description of a plurality of elements or components, unless it is apparent from the specific context that the plural is excluded. Moreover, when applied in this description and in all the following scope of patent application, the meaning of “in which” may include “in which” and “on which”, unless the context clearly specifies otherwise. Unless otherwise specified, the terms used throughout the specification and the scope of patent application generally have their usual meanings in the field, in the disclosure, and in the specific content. Certain terms used to describe the present invention will be discussed below or elsewhere in this specification to provide practitioners with additional guidance on the description of the present invention. Examples in any part of the entire specification, including examples of any terms discussed herein, are only for illustrative purposes and certainly do not limit the scope and meaning of the present invention or any illustrative terms. Similarly, the present invention is not limited to the various embodiments proposed in this specification.

The term “substantially”, “around”, “about”, or “approximately” used herein should generally mean within 20% of a given value or range, preferably within 10%. In addition, the quantity provided herein may be approximate, which means that it can be expressed using “around”, “about”, or “approximately”, unless otherwise stated. When there is a specified range, a preferred range, or upper and lower ideal values for quantity, concentration, or another value or parameter, it should be considered that all ranges formed by numerical pairs or ideal values of any upper and lower limits are disclosed particularly, regardless of whether the ranges are disclosed separately. For example, if a disclosed length ranges from X centimeters to Y centimeters, it should be considered that the disclosed length is H centimeters and H may be any real number between X and Y.

In addition, if the term “coupled” or “connected” is used, it herein includes any direct or indirect electrical connection means. For example, if the first device is electrically coupled to the second device as described in the text, it means that the first device may be directly connected to the second device, or indirectly connected to the second device by other devices or connection means. In addition, if the transmission or provision of an electrical signal is described, those skilled in the art should be able to understand that there may be attenuation or other non ideal changes during the transmission of the electrical signal. However, if there is no particular description of the source of the transmission or provision of the electrical signal and the receiving terminal, the electrical signal should be considered as the same signal substantially. For example, if an electrical signal S is transmitted (or provided) from a terminal point A of an electronic circuit to a terminal point B of the electronic circuit, a voltage drop may occur through two terminals of a source of a transistor switch and/or a stray capacitor. However, the purpose of this design is not to intentionally use attenuation or other non ideal changes generated during the transmission (or provision) to achieve certain specific technical effects, and the electrical signal S at the terminal points A and B of the electronic circuit should be considered as the same signal substantially.

It can be understood that the terms “comprising”, “including”, “having”, “containing”, “involving”, etc. used herein are open-ended, which means including but not limited to. Moreover, any one embodiment of the present invention or the scope of patent application does not necessarily achieve all the objectives, advantages, or characteristics disclosed in the present invention. In addition, the abstract and title are only intended to assist in the search for patent documents and are not intended to limit the scope of patent application for the present invention.

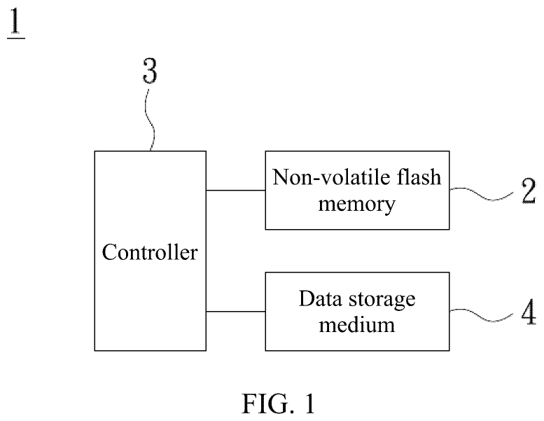

Reference is made to FIG. 1, which is a system block diagram of a data storage device provided by an embodiment of the present invention. The data storage device 1 provided by this embodiment includes a non-volatile flash memory 2, a controller 3, and a data storage medium 4, where the non-volatile flash memory 2 includes a plurality of data blocks, the data storage medium 4 stores a plurality of instructions, and the controller 3 is coupled to the non-volatile flash memory 2 and the data storage medium 4. The controller 3 is configured to execute the plurality of instructions for performing a data refresh method to access data in the plurality of data blocks of the non-volatile flash memory 2.

According to an embodiment of the present invention, the data storage device 1 may be a flash memory using a Universal Serial Bus (USB), Serial Advanced Technology Attachment (SATA), Parallel Advanced Technology Attachment (PATA) or Peripheral Component Interconnect (PCI) physical interface or using a USB, Non-Volatile Memory Express (NVME), Advanced Host Controller Interface (AHCI) or Small Computer System Interface (SCSI) communication protocol, such as a memory card, a USB flash device, a Solid-State Drive (SSD), an embedded Multi Media Card (eMMC), etc.

According to an embodiment of the present invention, the non-volatile flash memory 2 is, for example, but not limited to a NAND flash memory, and the type of the NAND flash memory is, for example, but not limited to, Single-Level Cell (SLC), Multi-Level Cell (MLC), Triple-Level Cell (TLC), Quad-Level Cell (QLC), and the like.

According to an embodiment of the present invention, the controller 3 is, for example, but not limited to a processor, a microprocessor, and the like, and is configured to execute writing, reading, erasing, and programming of the non-volatile flash memory 2 based on a command from a main control terminal such as the host and automatically performs the data refresh method of the data storage device 1 provided by this embodiment of the present invention.

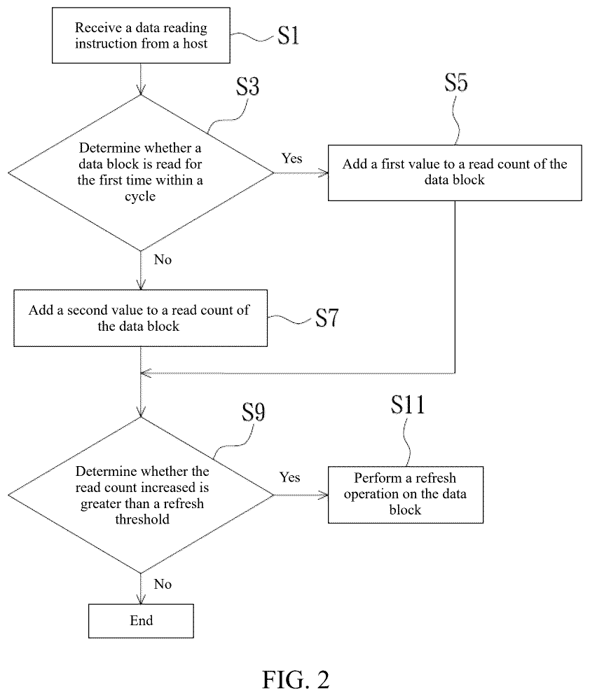

Reference is made to FIG. 2, which is a flowchart of steps of a data refresh method provided by an embodiment of the present invention. The data refresh method provided by this embodiment is performed by a controller 3 and includes the following steps. In step S1, a data reading instruction from a host is received, where the data reading instruction is, for example, an instruction for reading data in at least a data page of at least a data block in a non-volatile flash memory 2. In addition, the data page is a minimum unit readable for the data reading instruction.

In step S3, it is determined whether a data block is read for the first time within a cycle, where the data block is searched for based on the data reading instruction. Detailedly, in this embodiment, the cycle is represented by at least 120 seconds, substantially 120 seconds. However, in other embodiments, those skilled in the art may adjust the length of the cycle according to actual design and experience.

In step S5, in response to that the data block is read for the first time within the cycle, a first value is added to a read count of the data block. Detailedly, in this embodiment, the first value is represented by at least 120, substantially 120. For example, before the cycle, the read count of the data block is 100, and when the data block is read for the first time within the cycle of 120 seconds, the read count of the data block is 220 (100+120=220). However, in other embodiments, those skilled in the art may adjust the first value according to actual design and experience. Moreover, it is to be particularly noted that the start time of the cycle may be any time at which counting starts within a cycle. However, those skilled in the art may adjust the start time of the cycle according to actual design and experience.

In step S7, in response to that the data block is not read for the first time within the cycle, a second value is added to the read count of the data block. Detailedly, in this embodiment, when the data block is read for the second time, the third time . . . , the second value is added to the read count of the data block, respectively, where the second value is less than the first value and is, for example, 1. For example, the read count of the data block after being read for the first time within the cycle of 120 seconds is 220; when the data block is read for the second time within the cycle of 120 seconds, the read count of the data block is 221 (220+1=221); when the data block is read for the third time within the cycle of 120 seconds, the read count of the data block is 222 (221+1=222); and when the data block is read for multiple times within 120 seconds, the rest can be done in the same manner.

In step S9, it is determined whether the read count increased is greater than a refresh threshold. Detailedly, in this embodiment, the refresh threshold is represented by at least 50,000, substantially 50,000. However, in other embodiments, those skilled in the art may adjust the refresh threshold according to actual design and experience.

In step S11, in response to that the read count increased is greater than the refresh threshold, a refresh operation on the data block is performed. Detailedly, in this embodiment, when the read count of the data block is greater than the refresh threshold of 50,000, the refresh operation is performed on the data block to determine whether data therein is to be corrupted (an uncorrectable error correction code (UECC) occurs), and then it is determined whether the data is migrated into other data blocks.

In summary, according to the present invention, the weighted value is added to the read count of the data block frequently read within a cycle. Compared with a conventional count reading mode in which 1 is added to the read count of the data block when the data block is read once, the read count of the data block in the present invention reaches the refresh threshold more quickly, such that the refresh operation on the data block can be performed early and the impact of latent read disturbance on data blocks, data pages, and data can be avoided.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A data refresh method applicable to a data storage device comprising a non-volatile flash memory and a controller, wherein the non-volatile flash memory comprises a plurality of data blocks, and the data refresh method is performed by the controller which comprises:
receiving a data reading instruction from a host;
determining whether a data block is read for the first time within a cycle, wherein the data block is searched for based on the data reading instruction;
in response to that the data block is read for the first time within the cycle, adding a first value to a read count of the data block;
determining whether the read count increased is greater than a refresh threshold; and
in response to that the read count increased is greater than the refresh threshold, performing a refresh operation on the data block.

2. The data refresh method according to claim 1, further comprising:
in response to that the data block is not read for the first time within the cycle, adding a second value to the read count of the data block, wherein the second value is less than the first value.

3. The data refresh method according to claim 2, wherein the second value is 1.

4. The data refresh method according to claim 1, wherein the cycle is at least 120 seconds.

5. The data refresh method according to claim 1, wherein the first value is at least 120.

6. The data refresh method according to claim 1, wherein the refresh threshold is at least 50,000.

7. A data storage device, comprising:
a non-volatile flash memory comprising a plurality of data blocks; and
a controller coupled to the non-volatile flash memory and configured to perform a data refresh method;
wherein the data refresh method comprises:
receiving a data reading instruction from a host;
determining whether a data block is read for the first time within a cycle, wherein the data block is searched for based on the data reading instruction;
in response to that the data block is read for the first time within the cycle, adding a first value to a read count of the data block;
determining whether the read count increased is greater than a refresh threshold; and
in response to that the read count increased is greater than the refresh threshold, performing a refresh operation on the data block.

8. The data storage device according to claim 7, wherein the data refresh method further comprises:
in response to that the data block is not read for the first time within the cycle, adding a second value to the read count of the data block, wherein the second value is less than the first value.

9. The data storage device according to claim 8, wherein the second value is 1.

10. The data storage device according to claim 7, wherein the cycle is at least 120 seconds.

11. The data storage device according to claim 7, wherein the first value is at least 120.

12. The data storage device according to claim 7, wherein the refresh threshold is at least 50,000.

13. A data storage medium configured to store a plurality of instructions, wherein the plurality of instructions are executed by a controller to perform a data refresh method which comprises:
receiving a data reading instruction from a host;
determining whether a data block is read for the first time within a cycle, wherein the data block is searched for based on the data reading instruction;
in response to that the data block is read for the first time within the cycle, adding a first value to a read count of the data block;
determining whether the read count increased is greater than a refresh threshold; and
in response to that the read count increased is greater than the refresh threshold, performing a refresh operation on the data block.

14. The data storage medium according to claim 13, wherein the data refresh method further comprises:
in response to that the data block is not read for the first time within the cycle, adding a second value to the read count of the data block, wherein the second value is less than the first value.

15. The data storage medium according to claim 14, wherein the second value is 1.

16. The data storage medium according to claim 13, wherein the cycle is at least 120 seconds.

17. The data storage medium according to claim 13, wherein the first value is at least 120.

18. The data storage medium according to claim 13, wherein the refresh threshold is at least 50,000.
